(19) United States
(12) Patent Application Publication
(10) Pub. No.: US 2019/0139867 A1
(43) Pub. Date: May 9, 2019

(54) CHIP ON FILM PACKAGE STRUCTURE

(71) Applicant: Raydium Semiconductor Corporation, Hsinchu (TW)

(72) Inventor: CHING-YUNG CHEN, Taoyuan City (TW)

(21) Appl. No.: 16/184,005

(22) Filed: Nov. 8, 2018

Related U.S. Application Data
(60) Provisional application No. 62/583,636, filed on Nov. 9, 2017.

(51) Int. Cl. H01L 23/498; H01L 23/31; H01L 23/00; H01L 23/13; H01L 23/14

(52) U.S. Cl. CPC H01L 23/4985; H01L 23/3185; H01L 23/49838; H01L 23/145; H01L 23/562; H01L 23/13; H01L 23/49866

(57) ABSTRACT

A chip on film (COF) package structure used to package a chip is disclosed. The COF package structure includes a flexible substrate, a conductive layer, a plating layer and a solder resist layer. A conductive layer is formed on the flexible substrate. A plating layer is formed on the conductive layer and has an opening area. A solder resist layer is formed on the plating layer and connected to the conductive layer through the opening area. The solder resist layer has a single layer structure. A bending area is defined in the COF package structure. The bending area is enclosed in the opening area and the bending area is smaller than or equal to the opening area. When the bending area of the COF package structure is bent, no plating layer exists in the bending area, so that the bending resistance of the bending area can be enhanced

### BACKGROUND OF THE INVENTION

### 1. Field of the Invention

The invention relates to chip package; in particular, to a chip on film (COF) package structure.

### 2. Description of the Prior Art

Please refer to FIG. 1. FIG. 1 illustrates a schematic diagram of the conventional COF package structure. As shown in FIG. 1, in the conventional COF package structure 1, the laminated structure corresponding to the bending area BA is sequentially a flexible substrate 10, a conductive layer 12, a plating layer 14, and a solder resist layer 16 from bottom to top.

However, when the bending area BA of the conventional COF package structure 1 is bent, since the flexible substrate 10 has a certain thickness, and the plating layer 14 is plated on the conductive layer 12, both of them will cause poor bending resistance of the bending area BA of the conventional COF package structure 1, and there is still considerable room for improvement.

### SUMMARY OF THE INVENTION

Therefore, the invention provides a chip on film (COF) package structure to solve the above-mentioned problems.

A preferred embodiment of the invention is a chip on film (COF) package structure. In this embodiment, the COF package structure is used to package a chip. The COF package structure includes a flexible substrate, a conductive layer, a plating layer and a solder resist layer. The conductive layer is formed on a first surface of the flexible substrate. The plating layer is formed on the conductive layer and has an open area. The solder resist layer is formed on the plating layer and connected to the conductive layer through the open area. The solder resist layer has a single layer structure. A bending area is defined in the COF package structure. The bending area is enclosed in the open area and the bending area is smaller or equal to the open area. When the bending area of the COF package structure is bent, no plating layer exists in the bending area, so that a bending resistance of the bending area is enhanced.

In an embodiment, the flexible substrate is made of polyimide (PI) or other flexible materials.

In an embodiment, the conductive layer is made of copper or other conductive materials.

In an embodiment, the plating layer is made of tin or other plating materials.

In an embodiment, the flexible substrate has a first thickness, and a stress relief portion is formed on the flexible substrate within the bending area, at least a part of the stress relief portion has a second thickness smaller than the first thickness to enhance the bending resistance of the bending area.

In an embodiment, the stress relief portion is formed on a second surface of the flexible substrate, and the second surface and the first surface are opposite to each other.

In an embodiment, the stress relief portion is formed by laser trimming or wet etching.

In an embodiment, wires formed by the conductive layer within the bending area include at least one non-linear pattern.

In an embodiment, the at least one non-linear pattern is a snake-shaped pattern or a diamond-shaped pattern.

Another preferred embodiment of the invention is also a COF package structure. In this embodiment, the COF package structure is used to package a chip. The COF package structure includes a flexible substrate, a conductive layer, a plating layer and a solder resist layer. The flexible substrate has a first thickness. The conductive layer is formed on a first surface of the flexible substrate. The plating layer is formed on the conductive layer. The solder resist layer is formed on the plating layer. A bending area is defined in the COF package structure. A stress relief portion is formed on the flexible substrate within the bending area. At least a part of the stress relief portion has a second thickness smaller than the first thickness to enhance a bending resistance of the bending area.

Compared to the prior art, a laminated structure in a bending area of a COF package structure of the invention is improved, so that no plating layer exists in the bending area of the COF package structure and/or a thickness of at least a part of the flexible substrate within the bending area is thinned to effectively enhance a bending resistance of the bending area of the COF package structure. In addition, the wires formed of the conductive layer within the bending area include a non-linear pattern to also effectively enhance the bending resistance of the bending area of the COF package structure.

The advantage and spirit of the invention may be understood by the following detailed descriptions together with the appended drawings.

### BRIEF DESCRIPTION OF THE APPENDED DRAWINGS

FIG. 1 illustrates a schematic diagram of the luminated structure of the conventional COF package structure.

FIG. 2˜FIG. 6 illustrate schematic diagrams of the COF package structures in different embodiments of the invention respectively.

FIG. 7A˜FIG. 7C illustrate schematic diagrams of the wires formed of the conductive layer within the bending area including a linear pattern, a snake-shaped pattern and a diamond-shaped pattern respectively.

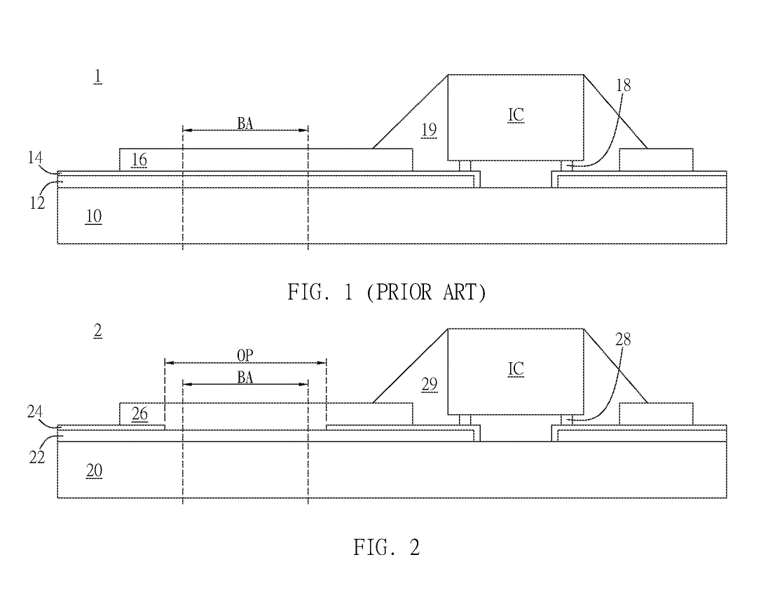

### DETAILED DESCRIPTION OF THE INVENTION

An embodiment of the invention is a chip on film (COF) package structure. In this embodiment, the chip on film package structure is used to package a chip on a flexible substrate, but not limited to this.

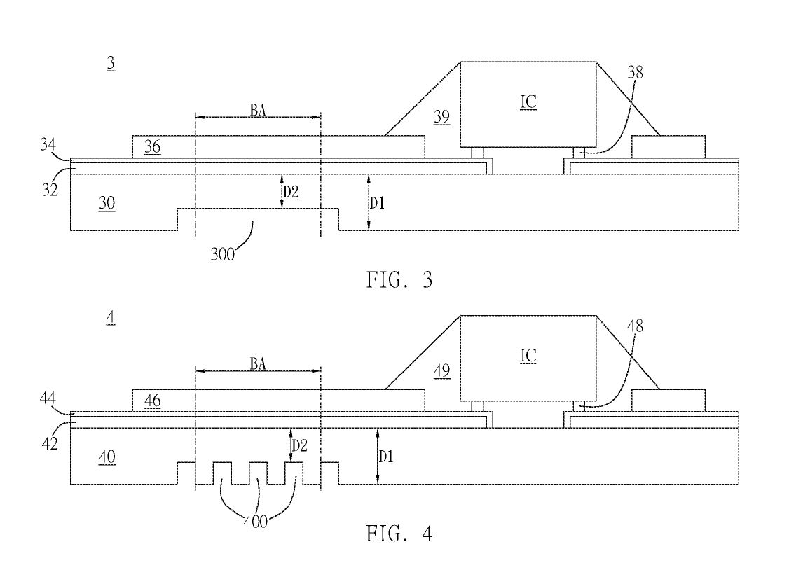

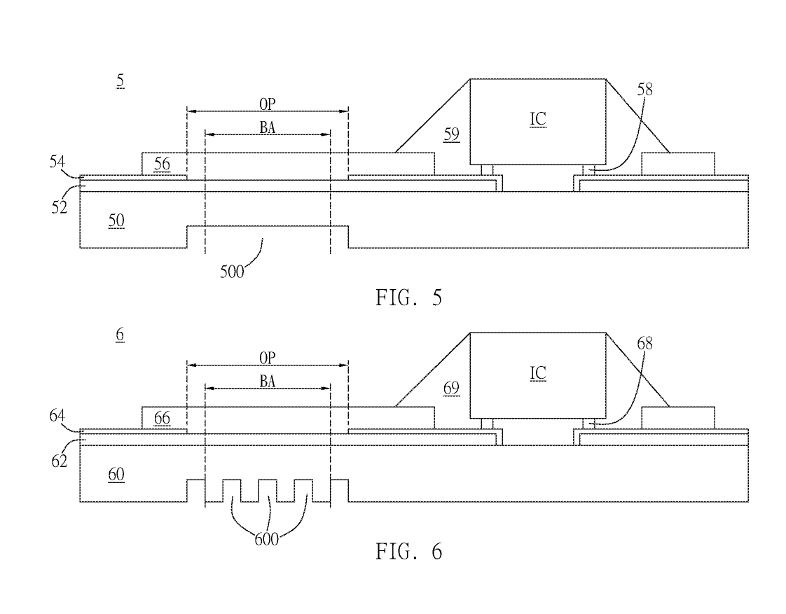

Please refer to FIG. 2. FIG. 2 illustrates a schematic diagram of the COF package structure in this embodiment. As shown in FIG. 2, the COF package structure 2 is used to package the chip IC. The COF package structure 2 includes a flexible substrate 20, a conductive layer 22, a plating layer 24, a solder resist layer 26, a connection terminal 28 and an encapsulation layer 29. In fact, the flexible substrate 20 can be formed of polyimide (PI) or other flexible material; the conductive layer 22 can be formed of copper or other conductive material; the plating layer 24 can be formed of tin or other plating materials, but not limited to this.

The conductive layer 22 is formed on the flexible substrate 20. The plating layer 24 is formed on the conductive layer 22 and has an open area OP. The solder resist layer 26 is formed on the plating layer 24 and connected to the conductive layer 22 through the opening area OP. The solder resist layer 26 has a single layer structure. The chip IC is disposed on the plating layer 24 through the connection terminal 28. The encapsulation layer 29 is filled between the chip IC and the flexible substrate 20 and between the flexible substrate 20 and the solder resist layer 26.

A bending area BA is defined in the COF package structure 2 and the COF package structure 2 can be bent through the bending area BA. The bending area BA is enclosed in the opening area OP and the bending area BA is smaller than or equal to the opening area OP. When the bending area BA of the COF package structure 2 is bent, no plating layer 24 exists in the bending area BA, so that a bending resistance of the bending area BA can be enhanced. In addition, since the solder resist layer 26 in this embodiment has the single layer structure, only a single solder resist coating process is required.

Then, please refer to FIG. 3. In another embodiment, the COF package structure 3 includes a flexible substrate 30, a conductive layer 32, a plating layer 34, a solder resist layer 36, a connection terminal 38 and an encapsulation layer 39.

The difference between the COF package structure 3 and the above-mentioned COF package structure 2 is that the flexible substrate 30 of the COF package structure 3 has a first thickness D1 and a stress relief portion 300 is formed on the flexible substrate 30 within the bending area BA in the COF package structure 3.

In fact, the stress relief portion 300 is formed on a second surface of the flexible substrate 30, and the second surface on which the stress relief portion 300 is disposed and the first surface on which the conductive layer 32 is disposed are opposite to each other. The stress relief portion 300 can be formed by laser trimming or wet etching, but is not limited to this. The shape and the size of the stress relief portion 300 can also be designed according to actual needs, as long as the thickness of at least a part of the flexible substrate 30 within the bending area BA is reduced, but not limited to this.

At least a part of the stress relief portion 300 has a second thickness D2, and the second thickness D2 is smaller than the first thickness D1. In this embodiment, the thickness of the flexible substrate 30 within the bending area BA is the second thickness D2 which is thinner than the first thickness D1. When the bending area BA of the COF package structure 3 is bent, it is easier to bend the bending area BA of the COF package structure 3 than the bending area BA of the conventional COF package structure 1, so that the bending resistance of the bending region BA of the COF package structure 3 can be effectively enhanced.

Next, please refer to FIG. 4. In another embodiment, the COF package structure 4 includes a flexible substrate 40, a conductive layer 42, a plating layer 44, a solder resist layer 46, a connection terminal 48 and an encapsulation layer 49.

The difference between the COF package structure 4 and the above-mentioned COF package structure 3 is that a stress relief portion 400 is formed on the flexible substrate 40 within the bending area BA, so that a part of the flexible substrate 40 within the bending area BA has the second thickness D2 thinner than the first thickness D1, but another part of the flexible substrate 40 still has the first thickness D1.

When the bending area BA of the COF package structure 4 is bent, it is still easier to bend the bending area BA of the COF package structure 4 than the conventional COF package structure 1, so that the bending resistance of the bending area BA of the bending area BA of the COF package structure 4 is enhanced. The shape and the size of the stress relief portion 400 can also be designed according to actual needs, as long as the thickness of at least a part of the flexible substrate 40 within the bending area BA is reduced.

Then, please refer to FIG. 5. In another embodiment, the COF package structure 5 includes a flexible substrate 50, a conductive layer 52, a plating layer 54, a solder resist layer 56, a connection terminal 58 and an encapsulation layer 59.

The COF package structure 5 combines the advantages of the above-mentioned COF package structure 2 and the COF package structure 3, and the bending area BA of the COF package structure 5 is enclosed in the open area OP of the plating layer 54 and the bending area BA is smaller than or equal to the opening area OP, and a stress releasing portion 500 is formed on the flexible substrate 50 within the bending area BA, so that the thickness of the flexible substrate 50 within the bending area BA is the second thickness D2 which is thinner than the first thickness D1.

Therefore, when the bending area BA of the COF package structure 5 is bent, no plating layer 54 exists in the bending area BA and the thickness of the bending area BA becomes thin, so that the bending resistance of the bending area BA is enhanced. In addition, since the solder resist layer 56 in this embodiment has a single layer structure, only a single solder resist coating process is required. The shape and the size of the stress relief portion 500 can also be designed according to actual needs, as long as the thickness of at least a portion of the flexible substrate 50 within the bending area BA is reduced, but not limited to this.

Next, please refer to FIG. 6. In another embodiment, the COF package structure 6 includes a flexible substrate 60, a conductive layer 62, a plating layer 64, a solder resist layer 66, a connection terminal 68 and an encapsulation layer 69.

The COF package structure 6 combines the advantages of the above-mentioned COF package structure 2 and the COF package structure 4, and the bending area BA of the COF package structure 6 is enclosed in the open area OP of the plating layer 64, and the bending area BA is smaller than or equal to the opening area OP, and the flexible substrate 60 within the bending area BA is formed with the stress relief portion 600, so that a part of the flexible substrate 60 within the bending area BA has the second thickness D2 which is smaller than the first thickness D1, and another part of the flexible substrate 60 still has the first thickness D1.

Therefore, when the bending area BA of the COF package structure 6 is bent, no plating layer 64 exists in the bending area BA and the thickness of the bending area BA is thinned, so that the bending resistance of the bending area BA is enhanced. In addition, since the solder resist layer 66 in this embodiment has a single layer structure, only a single solder resist coating process is required. The shape and the size of the stress relief portion 600 can also be designed according to actual needs, as long as the thickness of at least a part of the flexible substrate 60 within the bending area BA is reduced.

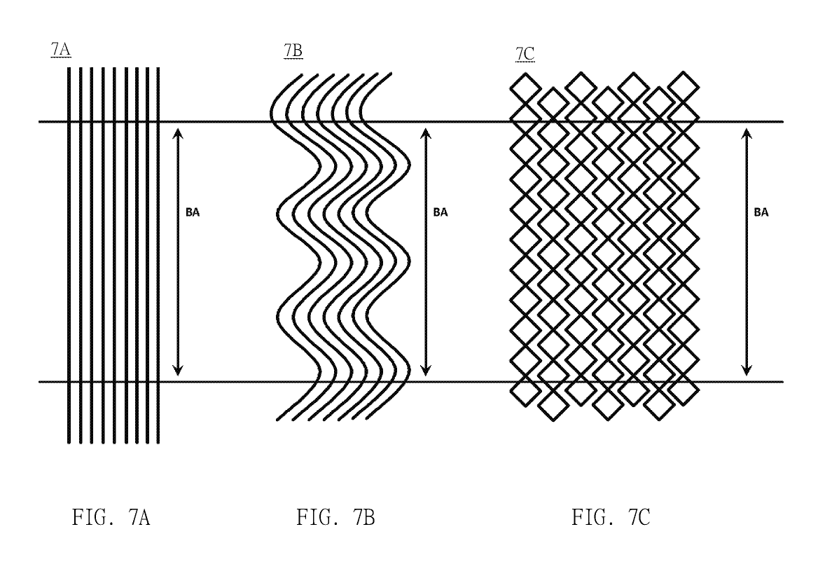

In addition, please also refer to FIG. 7A to FIG. 7C. The conductive layer formed in the bending area BA can include not only the conventional linear pattern 7A shown in FIG. 7A, but also the non-linear pattern, such as the snake-shaped pattern 7B shown in FIG. 7B or the diamond-shaped pattern pattern 7C shown in FIG. 7C to increase the bending resistance of the wires formed of the conductive layer within the bending area BA, but is not limited to this.

Compared to the prior art, a laminated structure in a bending area of a COF package structure of the invention is improved, so that no plating layer exists in the bending area of the COF package structure and/or a thickness of at least a part of the flexible substrate within the bending area is thinned to effectively enhance a bending resistance of the bending area of the COF package structure. In addition, the wires formed of the conductive layer within the bending area include a non-linear pattern to also effectively enhance the bending resistance of the bending area of the COF package structure.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A chip on film (COF) package structure, used to package a chip, the COF package structure comprising:
a flexible substrate;
a conductive layer, formed on a first surface of the flexible substrate;
a plating layer, formed on the conductive layer and has an open area; and
a solder resist layer, formed on the plating layer and connected to the conductive layer through the open area, and the solder resist layer having a single layer structure;
wherein a bending area is defined in the COF package structure, the bending area is enclosed in the open area and the bending area is smaller or equal to the open area, when the bending area of the COF package structure is bent, no plating layer exists in the bending area, so that a bending resistance of the bending area is enhanced.

2. The COF package structure of claim 1, wherein the flexible substrate is made of polyimide (PI) or other flexible materials.

3. The COF package structure of claim 1, wherein the conductive layer is made of copper or other conductive materials.

4. The COF package structure of claim 1, wherein the plating layer is made of tin or other plating materials.

5. The COF package structure of claim 1, wherein the flexible substrate has a first thickness, and a stress relief portion is formed on the flexible substrate within the bending area, at least a part of the stress relief portion has a second thickness smaller than the first thickness to enhance the bending resistance of the bending area.

6. The COF package structure of claim 5, wherein the stress relief portion is formed on a second surface of the flexible substrate, and the second surface and the first surface are opposite to each other.

7. The COF package structure of claim 5, wherein the stress relief portion is formed by laser trimming or wet etching.

8. The COF package structure of claim 1, wherein wires formed by the conductive layer within the bending area include at least one non-linear pattern.

9. The COF package structure of claim 8, wherein the at least one non-linear pattern is a snake-shaped pattern or a diamond-shaped pattern.

10. A chip on film (COF) package structure, used to package a chip, the COF package structure comprising:
a flexible substrate, having a first thickness;
a conductive layer, formed on a first surface of the flexible substrate;
a plating layer, formed on the conductive layer; and
a solder resist layer, formed on the plating layer;
wherein a bending area is defined in the COF package structure, a stress relief portion is formed on the flexible substrate within the bending area, at least a part of the stress relief portion has a second thickness smaller than the first thickness to enhance a bending resistance of the bending area.

11. The COF package structure of claim 10, wherein the flexible substrate is made of polyimide (PI) or other flexible materials.

12. The COF package structure of claim 10, wherein the conductive layer is made of copper or other conductive materials.

13. The COF package structure of claim 10, wherein the plating layer is made of tin or other plating materials.

14. The COF package structure of claim 10, wherein the stress relief portion is formed on a second surface of the flexible substrate, and the second surface and the first surface are opposite to each other.

15. The COF package structure of claim 10, wherein the stress relief portion is formed by laser trimming or wet etching.

16. The COF package structure of claim 10, wherein wires formed by the conductive layer within the bending area include at least one non-linear pattern.

17. The COF package structure of claim 16, wherein the at least one non-linear pattern is a snake-shaped pattern or a diamond-shaped pattern.
